(19) United States
(12) Patent Application Publication
(10) Pub. No.: US 2008/0164955 A1
(43) Pub. Date: Jul. 10, 2008

(54) VOLTAGE CONTROLLED OSCILLATOR CIRCUITS AND METHODS USING VARIABLE CAPACITANCE DEGENERATION FOR INCREASED TUNING RANGE

(76) Inventors: Ullrich R. Pfeiffer, Yorktown Heights, NY (US); Brian Welch, San Diego, CA (US)

Correspondence Address: Frank V. DeRosa, Esq.;F. CHAU & ASSOCIATES, LLC, 130 Woodbury Road, Woodbury, NY, 11797, US

(21) Appl. No.: 11/619,765

(22) Filed: Jan. 4, 2007

(51) Int. Cl. H03B 5/12

(52) U.S. Cl. 331/117 R; 331/177 V

(57) ABSTRACT

Voltage controlled oscillator circuits are provided in which variable capacitance degeneration is employed to provide increased tuning ranges and output amplitudes for VCO circuits for millimeter wave applications

### TECHNICAL FIELD OF THE INVENTION

The present invention relates generally to circuits and methods for implementing VCO (voltage controlled oscillator) circuits for millimeter wave applications. More specifically, the invention relates to circuits and methods for constructing LC voltage controlled oscillators using variable capacitance degeneration to provide increased tuning ranges for millimeter wave applications.

### BACKGROUND

In general, a VCO (voltage controlled oscillator) is an oscillator circuit that outputs an AC signal having a frequency that varies in response to an input control voltage. VCOs are fundamental components that are employed in a broad range of applications including radar and communications systems (e.g., wireline or wireless applications) for data transfer and recovery processes. By way of example, VCOs are utilized for PLL (phase Locked loop) circuits, DLL (delay locked loop) circuits, or injection locked oscillators. VCOs are further employed for applications such as frequency translation, data modulation, clock distribution and clock/data recovery.

FIG. 1 schematically illustrates a conventional voltage controlled oscillator circuit. More specifically, FIG. 1 is a circuit schematic of a conventional VCO circuit (10) comprising an oscillator core (11), a tank circuit (12) and a current source (13). The VCO (10) comprises an LC VCO topology based on the parallel resonance of inductors L and capacitors C in the tank circuit (12) The inductors L are illustrated as lumped elements and the capacitors C are illustrated as variable capacitors (14) (e.g., diode varactors). The variable capacitors (14) have a capacitance that may be varied by applying a tuning voltage Vtune1 for purposes of tuning the VCO (10) over a specified tuning range. The oscillator core (11) comprises a pair of cross-coupled transistors Q (e.g., bipolar junction transistors) with no emitter degeneration network. The current source (13) provides bias current for the cross-coupled transistors Q.

As is known in the art, the first order oscillation frequency of the cross-coupled LC VCO circuit (10) may be determined as:

$${f}_{osc} = \frac{1}{\sqrt{LC ( {V}_{tune} )}} \qquad ( 1 )$$

where the LC product is the resonant frequency of the VCO tank (12). The oscillator core (11) provides a “negative resistance” that is needed to compensate the losses of the tank circuit (12) in order to sustain oscillation. The tank circuit (12) includes a parallel parasitic resistance R_{P} that represents the resistive losses of the tank inductor L and capacitor C (e.g., varactor losses). For oscillation to occur, the negative resistance (−1/gₘ) provided by the: cross-coupled transistors Q has to be larger (in absolute value) than the parallel parasitic resistance R_{P} of the tank circuit (12):

R_{P}−(1/gₘ)≦0 (2).

In general, it is desirable to design VCOs having wide tuning ranges while minimizing phase noise. When designing a VCO, however, there is typically a tradeoff between tuning range and phase noise. For example, for the VCO circuit (10) of FIG. 1 having no emitter degeneration, the maximum attainable oscillation frequency and tuning range of the VCO is limited. More specifically, the turning range of the VCO circuit (10) can be increased by increasing the capacitance C of the tank (12) circuit. An increase in the capacitance C, however, results in increased loss of the tank circuit (12). The increase in loss may be offset by increasing the gain of the VCO circuit (10), but an increase in gain has the adverse effect of amplifying noise in the input signal to the VCO, resulting in increased phase noise.

Alternatively, the tuning range of a VCO having the conventional framework as depicted in FIG. 1 can be increased by decreasing the inductive load L of the LC lank circuit. Decreasing the inductive load L, however, decreases the quality of the tank and thereby increases the phase noise. In addition, reducing the inductive load L results in reduced voltage swing at the oscillator nodes which may prevent the VCO from oscillating.

Other conventional LC VCO circuit topologies implement what is known as fixed capacitance emitter degeneration to provide increased oscillation frequency and tuning ranges. By way of example, FIG. 2 schematically illustrates a conventional LC VCO circuit topology that implements fixed capacitance emitter degeneration. FIG. 2 illustrates an LC VCO circuit (20) comprising an oscillator core (21), a tank circuit (22) and a current source (23). The tank circuit (22) and current source (23) are similar in function to those discussed above with reference to FIG. 1.

The oscillator core (21) comprises a pair of cross-coupled transistors Q (e.g., bipolar junction transistors), with emitter degeneration provided by fixed capacitors Ce and resistors Re connected to the emitters of the cross-coupled transistors Q. By using fixed capacitive degeneration, the oscillation frequency approaches:

$${f}_{osc} = \frac{1}{\sqrt{L ( C ( {V}_{tune} ) - {C}_{e} )}} . \qquad ( 3 )$$

The conventional VCO framework of FIG. 2 allows for increased oscillation frequencies, as compared to the conventional VCO circuit (10) of FIG. 1. The following equations describe the effects of fixed capacitive degeneration on a cross-coupled oscillator core (21). In FIG. 2, Z_{IN} denotes the negative impedance of the oscillator core (21), where Z_{IN}=R_{EE}+jX_{EE}, where R_{EE} and X_{EE} respectively denote the real and imaginary part of the transformed negative impedance. To excite oscillation, R_{EE} must be negative. Consequently, the oscillation frequency occurs where X_{EE}=0. The following equations set forth conditions to sustain oscillation:

$$\begin{matrix}R > {R}_{EE} + \frac{{X}_{EE}^{2}}{{R}_{EE}} & ( 4 ) \\ {X}_{EE} = \frac{( {R}_{EE}^{2} + {X}_{EE}^{2} ) ( 1 - {ω}_{osc}^{2} LC )}{{ω}_{osc} L} & ( 5 )\end{matrix}$$

Furthermore, for the VCO (20) with fixed capacitance emitter degeneration, the following equations apply:

$$\begin{matrix}{R}_{EE} = \frac{1}{{g}_{m}} & ( 6 ) \\ {X}_{EE} = ( ω {L}_{E} - \frac{1}{ω {C}_{E}} ) \\ where \\ {L}_{E} = \frac{{C}_{π} {r}_{b}}{{g}_{m}} , & ( 7 )\end{matrix}$$

and where C_{π} denotes the base-emitter capacitance, r_{b} denotes the base resistance, and where gₘ denotes the conductance, such as described in the article by Zhan, et al., “Analysis of Emitter Degenerated LC Oscillators Using Bipolar Technologies”, Proceeding of IEEE International Symposium on Circuits and Systems, Bangkok, Thailand, May 25-28, 2003.

### SUMMARY OF THE INVENTION

By employing fixed capacitive degeneration, the tuning range and oscillation frequency of an LC VCO can be increased, with less power required to sustain oscillation. Despite this advantage, however, the performance of a VCO with fixed capacitive degeneration can be degraded under different bias conditions due to changes (increase or decrease) in the parasitic resistance R_{P} of the LC tank under such varying bias conditions. For instance, with the the conventional VCO framework of FIG. 2, depending of the type of varactors in the tank circuit (22) and the polarity of Vtune, a change in the bias conditions can increased the parasitic resistance R_{P} of the LC tank (22) (more energy being absorbed in the tank) which can suppress oscillation.

In general, exemplary embodiments of the invention include voltage controlled oscillator circuits employing variable capacitance degeneration to provide increased tuning ranges and output amplitudes for VCOs for use in millimeter wave applications. Exemplary embodiments of the invention include methods for utilzing variable capacitance degeneration for tuning/controlling VCO gain and the parasitic behaviors of active devices of the oscillator core, to thereby provide increased tuning range and output power across the full bandwidth of the oscillator at mllimeter wave operating frequencies.

For example, in one exemplary embodiment, a voltage controlled oscillator circuit includes a resonant circuit and an oscillator core coupled to the resonant circuit The resonant circuit has a resonant frequency that is controlled by a first control voltage to set an oscillation frequency of the VCO. The oscillator core provides a negative impedance that compensates losses of the resonant circuit and sustains oscillation of the VCO, wherein the oscillator core implements variable capacitive degeneration to adjust an amount of negative impedance provided by the oscillator core based on a second control voltage.

These and other exemplary embodiments, features and advantages of the present invention will be described or become apparent from the following detailed description of exemplary embodiments, which is to be read in connection with the accompanying drawings.

### BRIEF DESCRIPTION OF THE DRAWINGS

FIG. 1 schematically illustrates a conventional voltage controlled oscillator without emitter degeneration.

FIG. 2 schematically illustrates a conventional voltage controlled oscillator with fixed capacitance degeneration.

FIG. 3 schematically illustrates a voltage controlled oscillator with variable capacitance degeneration according to an exemplary embodiment of the invention.

FIG. 4 schematically illustrates a voltage controlled oscillator with variable capacitance degeneration according to another exemplary embodiment of the invention.

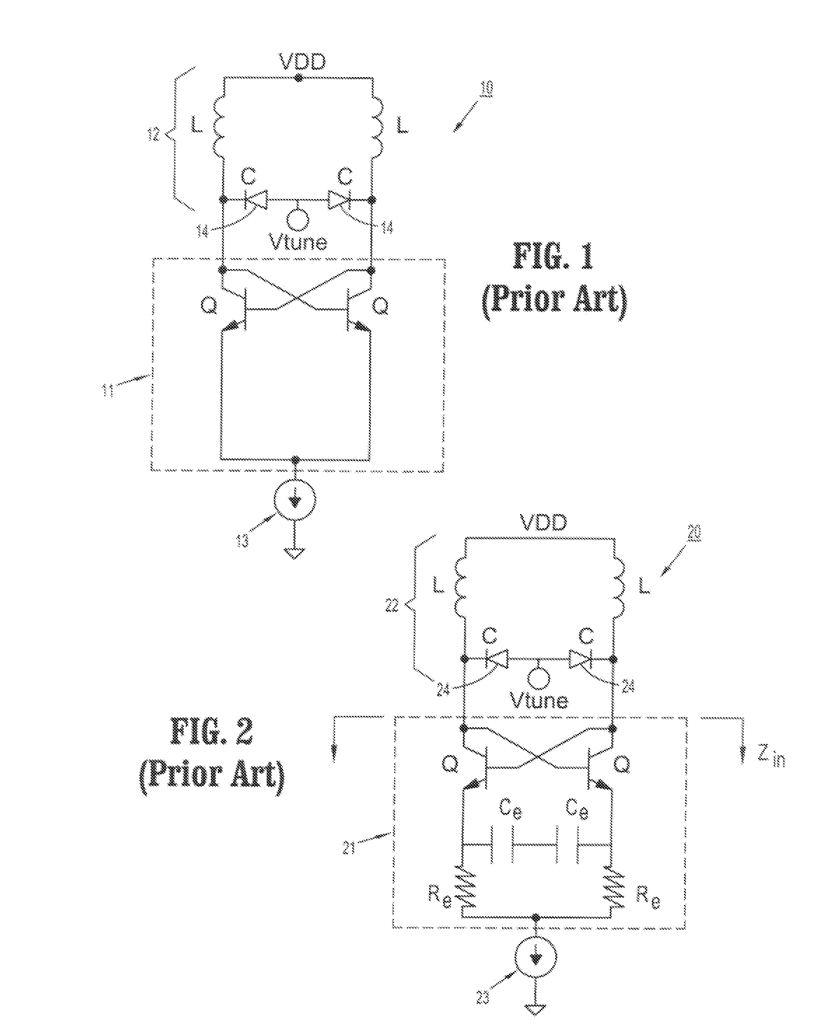

### DETAILED DESCRIPTION OF EXEMPLARY EMBODIMENTS

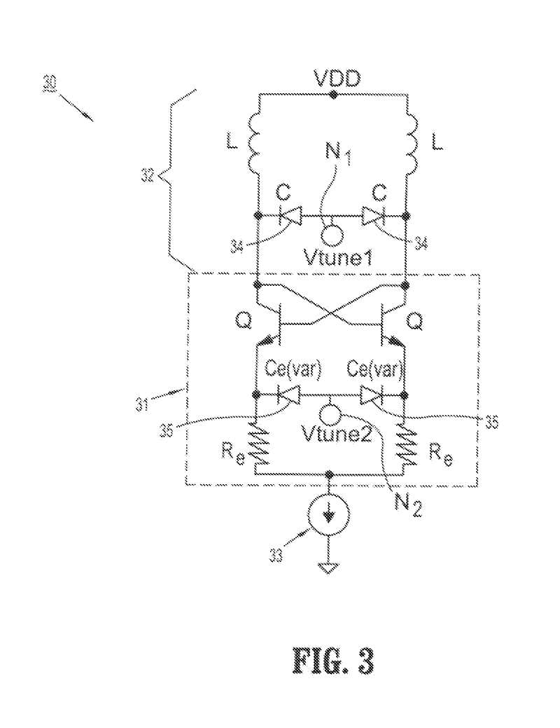

FIG. 3 schematically illustrates a voltage controlled oscillator with variable capacitance degeneration according to an exemplary embodiment of the invention. In particular, FIG. 3 illustrates an LC VCO circuit (30) which generally comprises an oscillator core (31), a resonant circuit (32) and a current source (33). The oscillator core (31) comprises a feedback circuit to compensate losses of the resonant circuit (32). As depicted in FIG. 3, the feedback circuit may be implemented using a pair of cross-coupled transistors Q (e.g., bipolar junction transistors or other types of transistors depending on the application). The resonant circuit (32) and current source (33) can be implemented using known circuit topologies.

The resonant circuit (32) may include parallel inductors L and variable capacitors C. The variable capacitors C are connected between the collector terminals of the transistors Q and commonly connected to a tuning voltage (Vtune1) input node N1. In one exemplary embodiment, the variable capacitors may be implemented using varactors (34) A varactor is a PN junction semiconductor, designed for microwave frequencies, in which the capacitance varies with the applied voltage.

Moreover, the oscillator core (31) comprises a degeneration network that includes a pair of variable capacitors Cₑ₍ᵥₐᵣ₎, which are connected between the emitter terminals of the transistors Q and commonly connected to a tuning voltage (Vtune2) input node N2. In one exemplary embodiment, the variable capacitors Cₑ₍ᵥₐᵣ₎ may be implemented using diode varactors (35). The degeneration network further comprises resistors Re connected to the emitters of the transistors Q. The resistors Re are connected in parallel with respective varactors (35), which serve to isolate the varactors (35).

In the exemplary embodiment of FIG. 3, the variable capacitors (e.g., varactors (34)) of the resonant circuit (32) provide a mechanism for tuning the oscillation frequency of the VCO (30) over a given tuning range in response to a first tuning voltage Vtune1 applied to node N1. Moreover, the variable degeneration capacitors Cₑ₍ᵥₐᵣ₎ (e.g., varactors (35)) provide a mechanism for turning the VCO (30) by varying the capacitive degeneration of the oscillator core (31) in response to a second tuning voltage Vtune2 applied to node N2. As explained in further detail below, variable capacitive degeneration enables fine tuning of VCO oscillation frequency over a wider tuning ranges as well as tuning the feedback gain of the oscillator core (31) under varying operating conditions to maintain efficient VCO performance.

In one exemplary embodiment of the invention, a common tuning voltage (e.g., Vtune1=Vtune2) can be commonly applied to both nodes N1 and N2. In another exemplary, embodiment, separate and distinct tuning control voltages (Vtune1, Vtune2) may be applied to respective tuning nodes N1 and N2, thereby allowing different variable tuning voltages to be applied to the resonant circuit (32) and the degeneration network in the oscillator core (31) for fine or coarse oscillation frequency tuning. For example, for reasonably sized varactors, the emitter varactors (35) will vary the oscillating frequency to a lesser extents than the collector varactors (34).

It is to be appreciated that the implementation of variable capacitive degeneration within the emitter degenerated oscillator core (31) provides for enhanced tuning ability and performance of the VCO (30) on various levels. For example, variable capacitor degeneration provides an additional mechanism for tuning the oscillation frequency of the VCO (30) by varying the parasitic capacitance seen by the negative resistance cell, i.e., oscillator core (31). In particular, the above Equation 3 can be modified by replacing the fixed degeneration capacitance Ce with a variable capacitance Cₑ₍ᵥₐᵣ₎ to yield:

$${f}_{osc} = \frac{1}{\sqrt{L ( C ( {V}_{tune 1} ) - {C}_{e ( var )} ( {V}_{tune 2} ) )}} \qquad ( 8 )$$

Here, as compared to the tuning range of a VCO with fixed capacitor degeneration Ce (e.g., FIG. 2), it is to be appreciated that the tuning range of a VCO with variable capacitor degeneration (e.g., FIG. 3) can provide an increased tuning range as a percent of the variation in, Cₑ₍ᵥₐᵣ₎ (Vₜᵤₙₑ₂₎, in circuit designs where the first order variations in the emitter degeneration capacitance have as much effect on the oscillation frequency as variations in the collector capacitance. However, the effect on oscillation frequency vis-à-vis the degeneration capacitance (e.g., varactors (35)) may be somewhat less than that of the collector capacitors (e.g., varactors (34)) when the two pairs of varactors (34), (35) are of similar size.

It is to be further appreciated that variable capacitance degeneration provides a mechanism for tuning the VCO gain. More specifically, variable capacitive degeneration enables the negative resistance of the cross-coupled pair (an effect of capacitive degeneration) to be adjusted for the purpose of tuning the oscillation amplitude of the VCO core (31) to account for variations in bias conditions of the collector-connected (tank) varactors (34) that cause increases or decreases in the parasitic resistance of the resonant circuit (32). The degree to which the parasitic resistance varies will depend on various factors such as the type of varactors (34)l that are employed, the polarity of the varactors (34), etc.

In accordance with exemplary embodiments of the invention, changes in bias conditions can be countered by varying the capacitive degeneration to increase/decrease the feedback gain of the cross-coupled pair and thereby appropriately adjust the negative resistance. For instance, when the parasitic resistance of the resonant circuit. (32) is increased, the feedback gain of the cross-coupled pair of transistors Q in the core (31) can be increased to maintain efficient VCO performance. Similarly, when the parasitic resistance of the resonant circuit decreases, the feedback gain can be appropriately decreased so as to maintain efficient VCO performance.

This can be illustrated by Equ. 7 above, where the fixed degeneration capacitor Ce can be replaced with the variable degeneration capacitance, Cₑ₍ᵥₐᵣ₎, such that XEE is variable with changes in the degeneration capacitance. In particular, an increase in the degeneration capacitance causes XEE to increase, which results in an increase in the feedback gain. On the other hand, a decrease in the degeneration capacitance causes XEE to decrease, which results in a decrease in the feedback gain.

In this regard, variable capacitive degeneration can be used to dynamically adjust the gain of the feedback circuit to minimize the amount of negative feedback needed under current operating conditions at a given time. Moreover, the ability to dynamically adjust the feedback gain via variable capacitive degeneration effectively enables control of the output power of the oscillator, e.g., increasing the gain of the feedback loop under high loss conditions. This is to be contrasted with conventional VCO designs with fixed capacitive degeneration (as in FIG. 2) where the negative resistance of the VCO core is selected to sustain VCO oscillation for a desired range of operating conditions but remains static. With fixed capacitive degeneration, in certain bias conditions, the negative resistance provided by the oscillator core may be more than necessary for low loss configurations, resulting in unnecessary waste of power.

It is to be further appreciated that variable capacitive degeneration provides a mechanism for reducing VCO phase noise and thus improving VCO performance. For example, as noted above, the degeneration varactors (35) can be tuned to increase the output amplitude of the VCO (30) under high loss bias conditions. According to Leeson's prediction, the phase noise in the 1/f² region at an offset frequency Δw from an oscillation frequency w_{OSC} is given by:

$$PNw ( Δ ω ) = kTR \frac{F}{{V}_{o}^{2}} {( \frac{{ω}_{osc}}{Q Δ w} )}^{2} \qquad ( 9 )$$

where k is Bolztmanns Constant, T is the absolute temperature, R is the VCO tank resistance (parasitic resistance Rp), Vₒ is the oscillation amplitude, F is the noise factor, and Q is the tank quality. According to Equ. 9, an increase in the parasitic resistance R can be offset by an increase in the oscillation amplitude Vo to thereby minimize the phase noise. Therefore, under high loss bias conditions, the degeneration varactors (35) can be tuned to increase the output amplitude of the VCO (30).

Moreover, with the exemplary VCO framework of FIG. 3, for example, reduced VCO phase noise is achieved by virtue of design as the degeneration capacitors (35) are subjected to low-pass filtering by their own RC network and by the cross-coupled negative resistance pair. In particular, improved phase noise is achieved since a portion of the tuning element of the oscillator is subjected to the noise filtering effects of RC degeneration and the cross-coupled pair. It is to be noted that while some thermal noise is introduced by the parasitic resistance of the emitter-connected varactors (35), most of the noise is contributed by the degeneration resistors Re, which are filtered in the same manner as with a fixed capacitance degeneration, i.e., with the emitter-connected varactors biased to provide more capacitance, the filtering abilities of the degeneration network are actually improved.

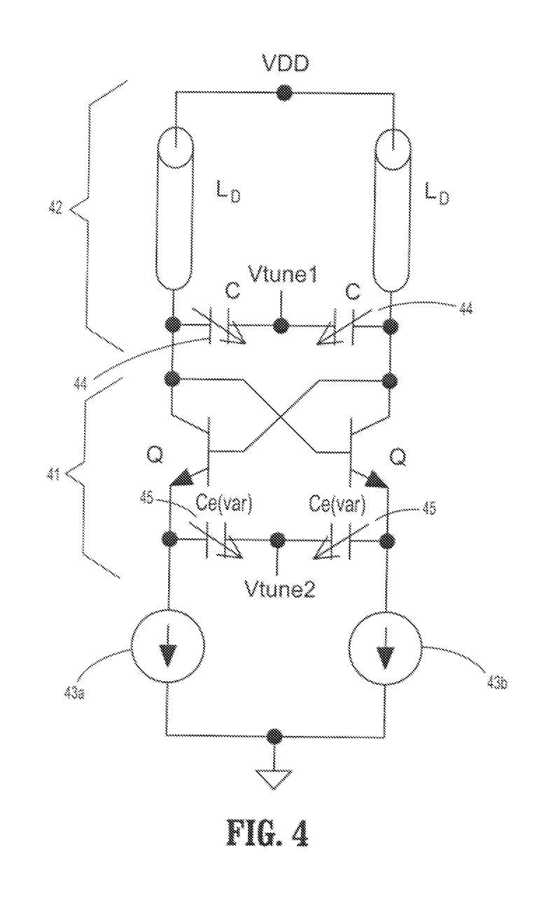

It is to be understood that FIG. 3 is merely one exemplary embodiment of a VCO with variable capacitor degeneration and that one of ordinary skill in the art could readily implement variable capacitor degeneration with other VCO circuit topologies. For example, FIG. 4 schematically illustrates a voltage controlled oscillator with variable capacitance degeneration according to another exemplary embodiment of the invention. In particular, FIG. 4 illustrates an LC VCO circuit (40) which generally comprises an oscillator core (41), a resonant circuit (42) and tail current sources (43a) and (43b). The core (41) includes a pair of cross-coupled transistors Q (e.g., bipolar junction transistors or other types of transistors depending on the application) and an emitter degeneration network comprising variable capacitors (45). The emitters of the cross-coupled transistor Q are connected to independent tail current sources (43a) and (43b), which serve to isolate the degeneration varactors (45). The resonant circuit (42) includes variable capacitors C, which may be implemented using diode varactor, and fixed inductor elements LD, which can be implemented using transmission lines (distributed inductor elements).

Although exemplary embodiments have been described herein with reference to the accompanying drawings, it is to be understood that the present invention is not limited to those exemplary embodiments, and that various other changes and modifications may be affected therein by one skilled in the art without departing from the scope or spirit of the invention. All such changes and modifications are intended to be included within the scope of the invention as defined by the appended claims.

We claim:

1. A VCO (voltage controlled oscillator) circuit, comprising:
a resonant circuit having a resonant frequency that is controlled by a first control voltage to set an oscillation frequency of the VCO; and
an oscillator core coupled to the resonant circuit to provide a negative impedance that compensates losses of the resonant circuit and sustains oscillation of the VCO,
wherein the oscillator core implements variable capacitive degeneration to adjust an amount of negative impedance provided by the oscillator core based on a second control voltage.

2. The VCO of claim 1, wherein the resonant circuit comprises an LC resonant circuit having a tunable capacitance that is controlled using the first control voltage to adjust the oscillation frequency.

3. The VCO of claim 1, wherein the oscillator core comprises a cross-coupled pair of transistors.

4. The VCO of claim 2, wherein the transistors are bipolar junction transistors.

5. The VCO of claim 1, wherein the oscillator care comprises a degeneration network having a tunable capacitance that is controlled using the second control voltage to adjust the capacitive degeneration.

6. The VCO of claim 5, wherein the degeneration network comprises varactors to provide the tunable capacitance.

7. The VCO of claim 6, wherein the degeneration network comprises resistors connected in parallel with the varactors.

8. The VCO of claim 1, further comprising a tail current source to bias the cross-coupled pair of transistors.

9. A VCO (voltage controlled oscillator) circuit, comprising:
a LC resonant circuit having a fixed-value inductance and a tunable capacitance that is controlled by a first control voltage to set an oscillation frequency of the VCO; and
an oscillator core comprising a cross-coupled pair of bipolar junction transistors and an emitter degeneration circuit which provides variable capacitive degeneration under control of a second control voltage.

10. The VCO of claim 9, wherein the emitter degeneration network comprises a pair of degeneration varactors serially connected between emitter terminals of the bipolar junction transistors and commonly connected to a second control node to which the second control voltage is applied.

11. The VCO of claim 10, wherein the emitter degeneration network further comprises a pair of degeneration resistors connected in parallel with the pair of degeneration varactors.

12. The VCO of claim 10, further comprising at least one tail current source for providing a constant bias current to bias the transistors.

13. The VCO of claim 10, wherein the resonant circuit comprises a pair of varactors serially connected between collector terminals of the bipolar junction transistors and commonly connected to a first control node to which the first control voltage is applied.

14. The VCO of claim 13, wherein the resonant circuit comprises printed transmission lines providing the fixed inductance of the resonant circuit.

15. The VCO of claim 1, wherein the capacitive degeneration is controlled by the second control voltage to adjust an amount of negative impedance provided by the oscillator core.

16. The VCO of claim 1, wherein the capacitive degeneration is controlled by the second control voltage to adjust the oscillation frequency of the VCO.

17. The VCO of claim 1, wherein the capacitive degeneration is controlled by the second control voltage to adjust an amount of gain of the oscillator core.

18. The VCO of claim 1, wherein the capacitive degeneration is control by the second control voltage to decrease phase noise.

19. A method for operating a VCO (voltage controlled oscillator), comprising:
applying a first control voltage to a first control port of the VCO to set an oscillation frequency of the VCO; and
applying a second control voltage to a second control port of the VCO to control variable capacitive degeneration of a VCO core and tune a negative impedance provided by the VCO core.

20. The method of claim 19, wherein the capacitive degeneration of the VCO core is adjusted to vary a parasitic capacitance of the VCO core to tune the oscillation frequency.

21. The method of claim 19, wherein the capacitive degeneration of the VCO core is adjusted to tune the negative impedance for adjusting an oscillation amplitude of the VCO core.
